(19) United States
(12) Patent Application Publication
(10) Pub. No.: US 2009/0072279 A1
(43) Pub. Date: Mar. 19, 2009

(54) Capacitor-less memory and abrupt switch based on hysteresis characteristics in punch-through impact ionization mos transistor (PI-MOS)

(75) Inventors: Kirsten Moselund, Lausanne (CH); Mihai Adrian Ionescu, Ecublens VD (CH); Vincent Pott, Bramois (CH); Maher Kayal, St-Sulpice (CH)

Correspondence Address: NIXON & VANDERHYE, PC, 901 NORTH GLEBE ROAD, 11TH FLOOR, ARLINGTON, VA, 22203, US

(73) Assignee: ECOLE POLYTECHNIQUE FEDERALE DE LAUSANNE (EPFL), Lausanne (CH)

(21) Appl. No.: 12/230,557

(22) Filed: Aug. 29, 2008

Related U.S. Application Data
(60) Provisional application No. 60/968,651, filed on Aug. 29, 2007.

(51) Int. Cl. H01L 29/78; H03K 17/16

(52) U.S. Cl. 257/288; 327/389; 257/E29.255

(57) ABSTRACT

The present invention exploits the impact ionization induced by drain voltage increase and the onset of a bipolar parasitic in an Ω-gate field effect metal oxide insulator transistor (called PI-MOS), in order to obtain a memory effect and abrupt current switching.

The present application claims priority of U.S. Ser. No. 60/968,651, the content of which is incorporated by reference in its entirety in the present application.

### BACKGROUND OF THE INVENTION

The present invention concerns the field of transistors, in particular, a class of devices that can offer abrupt off-on transitions and intrinsic mechanisms for capacitor-less memory applications; the proposed device is called punch-through impact ionization Metal Oxide Semiconductor (PI-MOS transistors).

### PRINCIPLE OF THE INVENTION

The present invention exploits the impact ionization induced by drain voltage increase and the onset of a bipolar parasitic in an Ω-gate field effect metal oxide insulator transistor (called PI-MOS), in order to obtain a memory effect and abrupt current switching. Under certain bias conditions it is possible to achieve very abrupt current switching (less than 10 mV per decade of current) as well as a hysteresis behavior in the gate and drain voltage characteristics.

The switching efficiency is well beyond the 60 mV/decade limit found for conventional MOSFET devices, and thus by proper tailoring of device parameters such a switch could be of great interest for low power applications. The hysteresis in gate bias spans up to few volts of V_{G} (2V demonstrated) and thus ranges from the subthreshold to the moderate inversion regime of operation, the difference in current level is about 2-3 decades of current, depending on device geometry.

In one embodiment, a 1T (one transistor) DRAM memory cell and a 1T SRAM cell are proposed based on the exploitation of the hysteresis appearing in the drain current versus drain voltage characteristics and its combination with the hysteresis in the drain current versus gate voltage, respectively.

In another embodiment, a 1T-1PI-MOS memory cell is proposed to further reduce power consumption.

In a further embodiment, an abrupt switch with dynamic threshold voltage transitions and the use of these threshold voltages to define a one-device (PI-MOS) based Schmitt trigger (or double-threshold comparator) operation are proposed.

### BRIEF DESCRIPTION OF THE DRAWINGS

FIG. 1 (a) is three dimensional drawing of the Ω-gate MOS device according to the invention.

FIG. 1 (b) is a cut along the channel of an Ω-gate MOS device according to the invention; the constituting regions are: 1—low doped P type silicon discussed, 2—highly doped N type silicon, 3—gate insulator (such as silicon dioxide or high-k dielectrics), 4—gate conductor (such as highly doped polycrystalline silicon or metals). Source, drain, gate and body contacts are also shown.

FIG. 2 depicts various cross-sections of the device on bulk silicon: (a) Ω-gate, (b) quasi-planar gate (or large width of Ω-gate), (c) tri-gate, (d) FIN-gate.

FIG. 2 (e) shows a fabricated Ω-gate PI-MOS device on bulk silicon and related scale of dimensions.

FIG. 2 (f) shows a fabricated quasi-planar PI-MOS device and related scale of dimension.

FIG. 2 (g) shows a fabricated tri-gate PI-MOS device and related scale of dimensions.

FIG. 3 is a process flow (channel cross-section) for an Ω-gate MOSFET according to the present invention.

FIG. 4 is an illustration of an abrupt switching and hysteresis in the I_{D}(V_{D}) characteristics for the drain current.

FIG. 5 is an illustration of hysteresis in I_{D}(V_{DS}) characteristic.

FIG. 6 is a gate switching I_{D}(V_{G}) hysteresis measured in a Ω-gate device.

FIG. 7 is an hysteresis in I_{D}(V_{GS}) characteristic.

FIG. 8 illustrates a simulation of the electrostatic potential distribution in the silicon body of a device.

FIG. 9(a) illustrates a potential profile cut along channel at a depth of 0.1 μm and

FIG. 9(b) illustrates a potential profile Cut through channel center.

FIG. 10(a) illustrates a drain current snapback in VDS (solid lines) measured using current biasing and

FIG. 10(b) illustrates a schematic of PI-MOS showing the bipolar action which is present in the avalanche region.

FIG. 11 illustrates effect of temperature (from 25° C. to 135° C. on ID (solid lines) and IB (dotted lines) hysteresis for a PI-MOS device.

FIG. 12 illustrates as alternative biasing scheme the source with a negative bias.

FIG. 13 (a) shows four different graded doping profiles for PI-MOS optimization.

FIG. 13 (b) depicts the effects of breakdown voltage and drain current of the four different doping cases from FIG. 13(a): (1) Constant at 5×10¹⁶ cm⁻³. (2) Graded from 1.5×10¹⁷ cm⁻³ at the surface to 5×10¹⁶ cm-3 in the bulk. (3) Graded from 2.5×10¹⁷ cm⁻³ at the surface to 5×10¹⁶ cm⁻³ in the bulk. (4) Constant at 1×10¹⁷ cm⁻³. These results correspond to a channel length for the simulations L=300 nm, a junction depth, xj=80 nm, and a silicon dioxide thickness, tox=2 nm.

FIG. 14 shows a 1T DRAM structure using a single PI-MOS transistor with accompanying truth-table.

FIG. 15 illustrates the demonstration of the hold operation by pulling the V_{GS} low on the write “1”, read “1” cycle.

FIG. 16 shows a 1T SRAM structure using a single PI-MOS transistor with accompanying truth-table.

FIG. 17 illustrates the demonstration of the 1T SRAM hold operation by pulling the VGS low on the write ‘1’, read ‘1’ cycle.

FIG. 18 shows a Schematic 1PI-MOS-1T DRAM architecture.

FIG. 19 illustrates a demonstration of the DRAM levels for both write and read.

FIG. 20 (a) shows retention time measurements for a device.

FIG. 20(b) shows 10 successive hysteresis cycles measured after >10⁴ cycles of operation of a PI-MOS memory cell.

FIG. 21 shows a plot of breakdown/pull-up voltage as a function of channel length.

### DETAILED DESCRIPTION OF THE INVENTION

### 1. PI-MOS Device Structure:

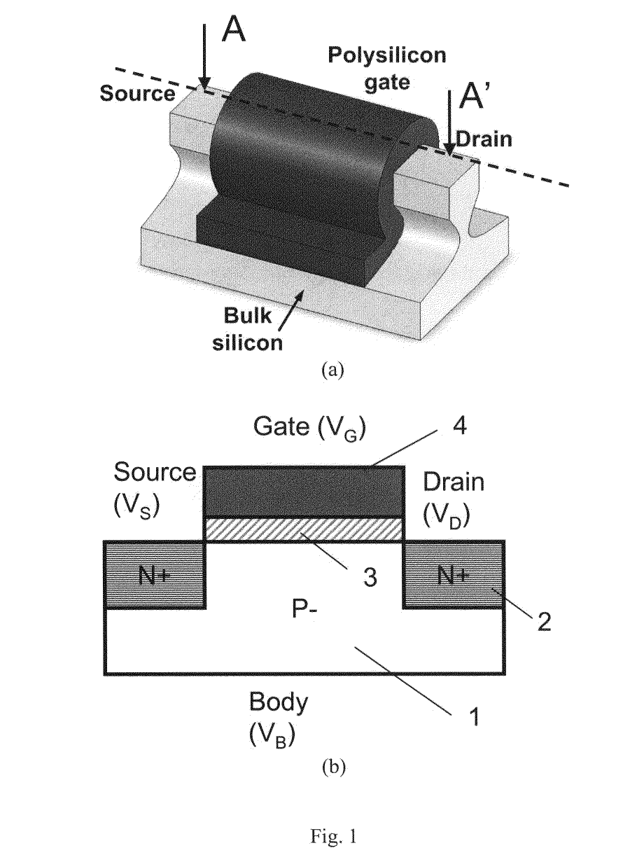

A three dimensional device drawing is shown in FIG. 1 (a). The channel region is low doped and surrounded by a gate stack, comprising a gate dielectric (silicon dioxide or other gate insulators for silicon field effect transistors, such as high-k dielectrics) and a conducting gate material (such as highly doped poly-silicon or metals). FIG. 1 (b) depicts a cross section of the device from FIG. 1 along the AA′ line and the related regions: 1—low doped P-type silicon (body), 2—highly doped (˜10²⁰ cm⁻³) N-type silicon (source and drain), 3—gate insulator (such as silicon dioxide or high-k dielectrics), 4—gate conductor (such as highly doped polysilicon or metals). The source and drain in the current embodiment consists of a high doping implantation of the opposite type as the channel region, i.e. n-type for a NMOS configuration. However, for future implementations the source and drain diffusions could be replaced by a metal-semiconductor Schottky junctions.

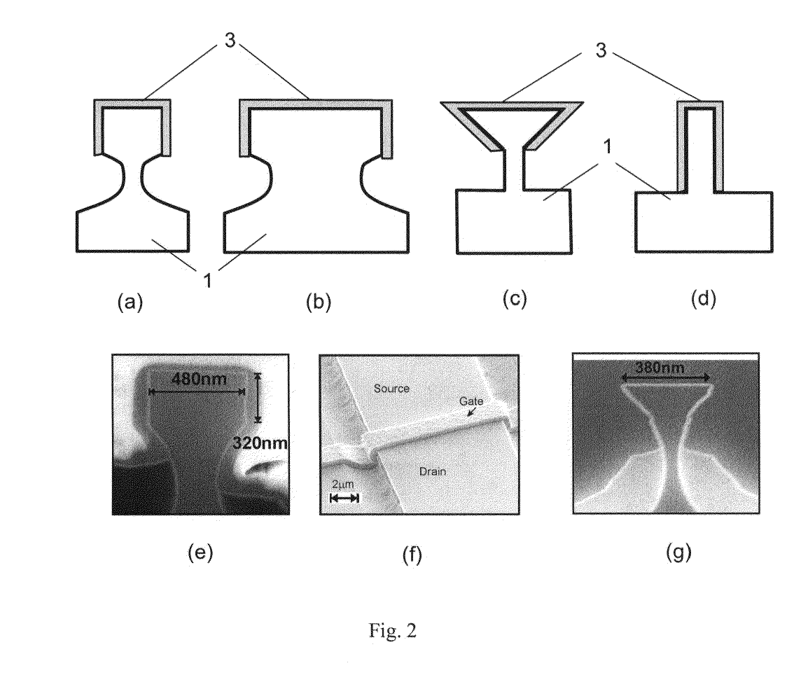

FIG. 2 depicts various cross-sections of the device on bulk silicon: Ω-gate (FIG. 2a), quasi-planar gate or large width of Ω-gate (FIG. 2b), tri-gate (FIG. 2c), FIN-gate (FIG. 2d). Cross-sections of some fabricated Ω-gate, quasi-planar and tri-gate devices are reported in FIGS. 2 (e), (f), (g), respectively. The practical dimensions of the device cross sections can vary from tens of nanometers to micrometers.

The length and doping profile of the channel should be tailored to operate in the punch-through condition, thus the longer the channel the lower should be the doping of the substrate. For doping concentration greater than approximately 5×10¹⁴ cm⁻³ the physical length should be smaller than or equal to approximately 10 μm. For a much smaller channel length of 100 nm, a doping of the silicon channel of the order of 10¹⁷ cm⁻³ creates the necessary conditions for punch-through and PI-MOS operation; for even smaller channel length this value can be increased.

The width of the device, in FIG. 2 (e) indicated as 480 nm, can be either greater or smaller than this value converging towards a quasi-planar device at large widths, FIG. 2 (f). However, too large a width might lead to a poorer hysteresis profile in V_{GS} due to reduced charge gate control.

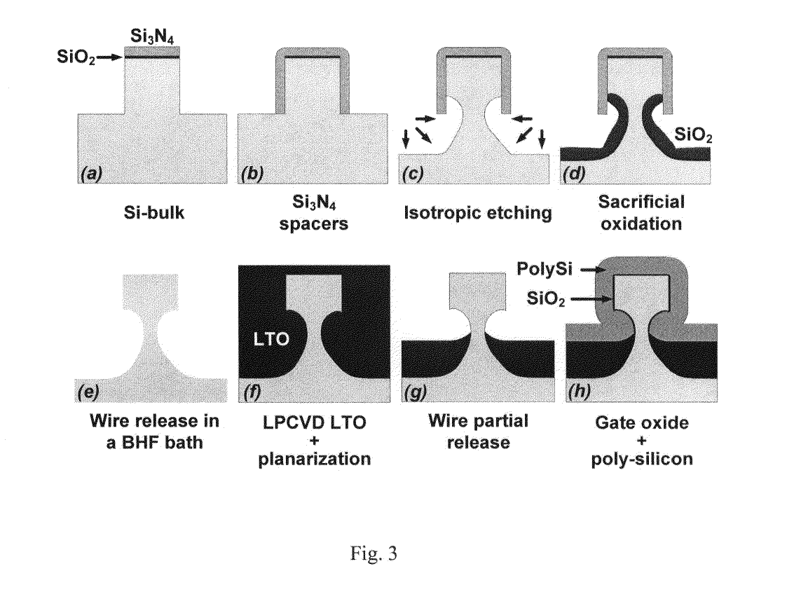

The Ω-MOSFET devices are fabricated according to the process flow depicted in FIG. 3 where a process flow (channel cross-section) for an Ω-gate MOSFET is illustrated. The shape and size of the wire is determined by the lithographic width and silicon etch depth (step a-b), the isotropic etching (step c) and the sacrificial oxidation (step d). The substrate is low doped (high-resistivity: 15-25Ω·cm) p-type Si-bulk. A silicon rib of 1 μm depth is first dry-etched using fluorine chemistry and a hard mask of 15 nm SiO₂ and 80 nm Si₃N₄ (step a). A sacrificial oxidation of 300 nm can be performed in order to smooth the sidewalls, and to reduce the horizontal dimensions in a controllable fashion. The sacrificial oxide is removed in a BHF bath and 35 nm thick nitride spacers are deposited (step b).

An isotropic silicon etch is used to partially underetch the nanowire (step c). A second oxidation follows to repair any etching damage and reduce the dimensions even further (step d). The thermal oxide is removed (step e) and replaced by a deposited LPCVD low temperature oxide (LTO). The LTO is planarized in a chemical-mechanical polishing (CMP) step (step f), and partially removed to expose the silicon Ω-structure in the regions where the MOSFET is implemented. An oxide is maintained on the Si bulk surface to isolate the device (step g).

A gate stack consisting of 10 nm thermal oxide and 100 nm poly-silicon (reduced to approximately 90 nm, during subsequent oxidation steps) is created (step h). The poly-silicon gate is patterned and isotropically etched, and a self-aligned implantation step of gate, source and drain is carried out (Arsenic, 5×10¹⁵ cm⁻², 40 keV, Tilt=7°) using a 40 nm thick implantation oxide, which is subsequently removed. The doping is finally activated by an annealing step at 950° C. for 10 min.

### 2. PI-MOS Device Characteristics:

In one embodiment the source bias, V_{S}, is placed at ground potential and the other three bias levels are measured with respect to V_{S}.

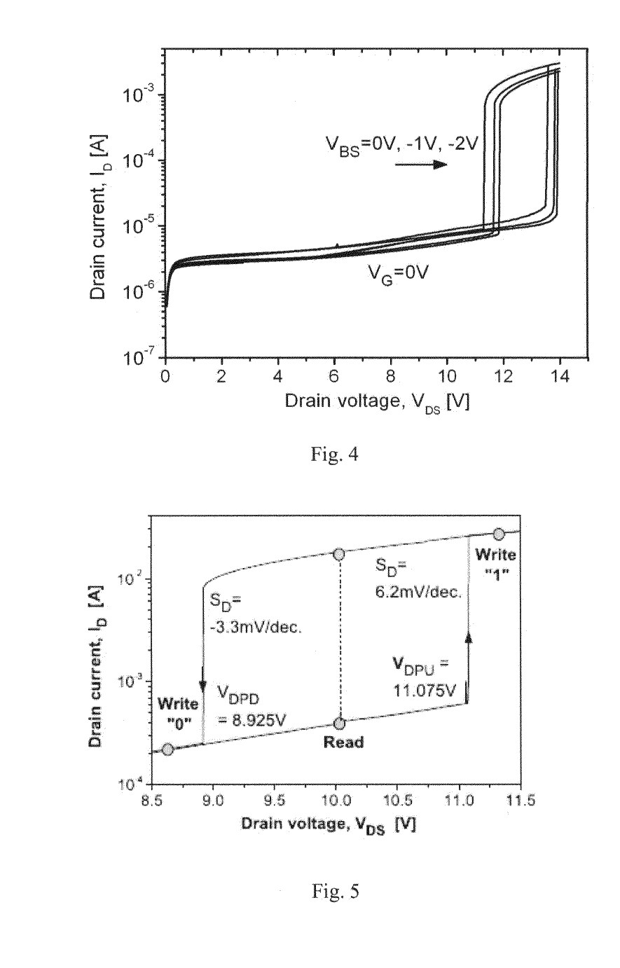

The device must operate in the punch-through condition determined by the drain to source bias V_{DS}, typical hysteresis curve in I_{D}(V_{DS}) for a gate bias V_{GS}=0V and source bias V_{S}=0V are shown for the drain current, FIG. 4 which shows an abrupt switching and hysteresis in the I_{D}(V_{D}) characteristics for the drain current. The three different characteristics represent different levels of substrate bias. The device has a gate length 4.2 μm, and effective width 2.0 μm. A similar hysteresis behavior is observed in the body (substrate) current. The substrate bias (V_{BS}=0V, −1V, −2V, in FIG. 4) results in a slight shift of the characteristics, but has a limited influence on the current level.

FIG. 5 depicts a typical ID(VDS) hysteresis loop with abrupt pull-up and pull-down transitions and the associated memory window with WRITE ‘0’, WRITE ‘1’ and READ voltages (in the middle). The hysteresis in I_{D}(V_{DS}) characteristic and its application for memory operation for a device of L=1.4 μm and width Weff=40 μm, for V_{GS}=−0.5V and V_{BS}=0V, the slopes S_{D} are defined as the inverse of the logarithmic low-high and high-low transients in I_{D}(V_{DS}), similarly to the subthreshold slope for a MOSFET, and it takes on a value ranging from 3-6 mV/dec. V_{DPU} and V_{DPD} are the pull-up and pull-down voltages in the drain hysteresis.

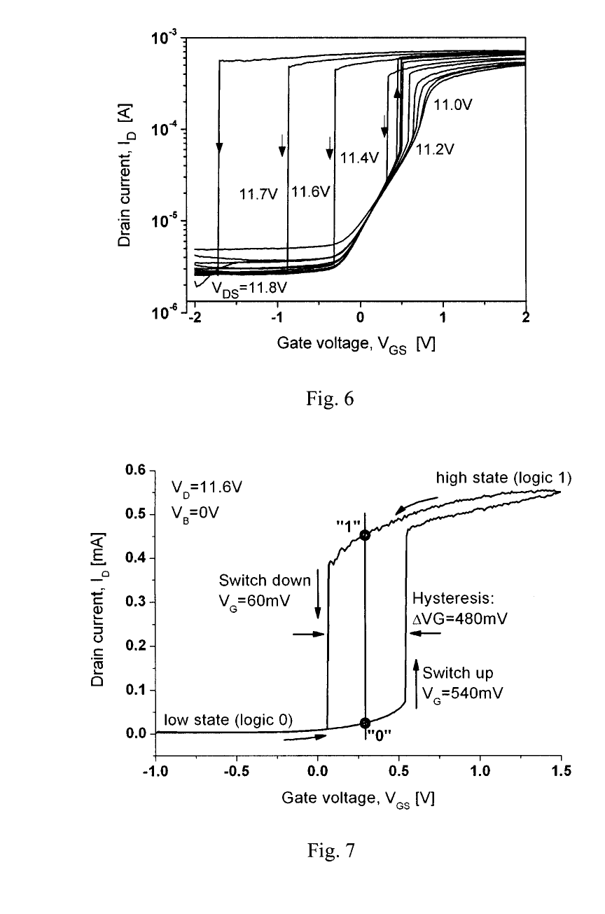

By applying a fairly high VDS, and tracing the ID(VGS) characteristics, one can observe a similar hysteresis characteristic, this is shown in FIG. 6: a gate switching ID(VG) hysteresis measured in a 4.2 μm long Ω-gate device. VD is 11.6V and VB=0. The abrupt pull-up voltage is VG=540 mV while the pull-down occurs at VG=60 mV. The device threshold voltage is VT˜0V.

In FIG. 7 hysteresis in I_{D}(V_{GS}) characteristic and its application for memory operation is represented. By adjusting VDS it is possible to achieve a hysteresis of up to 2-3 decades of current and with a width of approximately 2V, and with slopes both for the switch down and switch of about 5-10 mV/decade of current. FIG. 7 shows a typical I_{D}(V_{GS}) hysteresis loop with abrupt pull-up and pull-down transitions and the associated memory window with WRITE ‘0’, WRITE ‘1’ and READ voltages (in the middle).

### 3. PI-MOS Device Functionality:

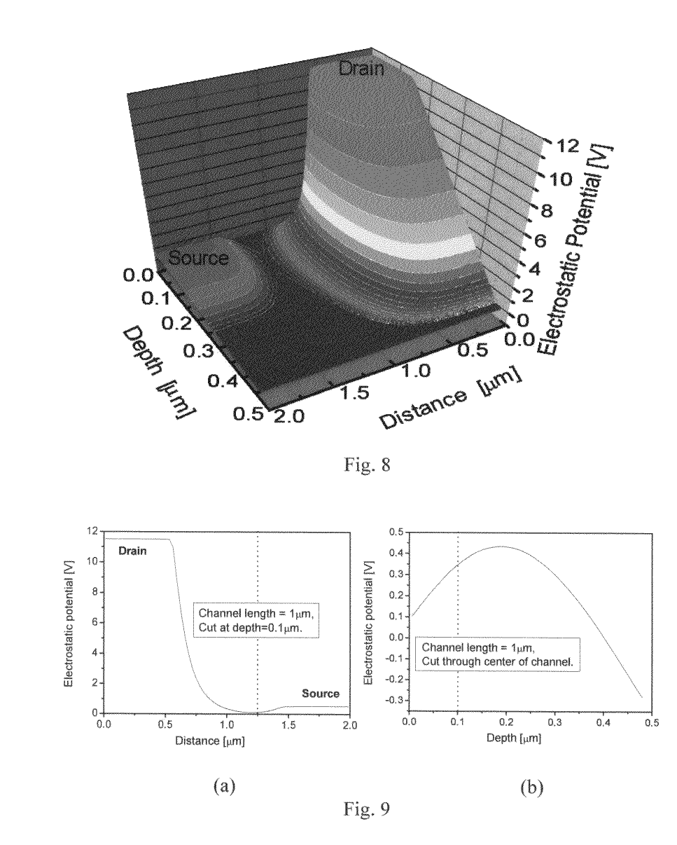

FIGS. 8 and 9 show the distribution of the electrostatic potential along the (short) channel of the PI-MOS device. More precisely, FIG. 8 illustrates the simulation of the electrostatic potential distribution in the silicon body of a device of channel length 1 um. N_{A}=8×10¹⁴ cm⁻³. The device is biased in weak inversion: V_{GS}=−0.4V, V_{DS}=11V, V_{BS}=0V.

For V_{GS}=−0.4V (subthreshold), V_{DS}=11V (punch through), V_{BS}=0V. In [1] it was shown that under conditions of channel punch-through, there exists a potential pocket close to the channel, bordered by a saddle point in the channel, as shown in FIGS. 8 and 9. The simulation also suggests that the depth of the substrate under the gate has an impact on the position of the saddle point, which shifts towards the source with increasing substrate depth. This may partly explain the very good hysteresis in our body-tied Ω-MOSFET, since the edge part corresponds to a simulation with a fairly shallow substrate.

With the existence of the potential saddle point under the gate and close to the surface of the Ω-gate PI-MOS, the phenomena of abrupt switching and hysteresis can be explained similarly to [2]. When the drain bias is increased, the electric field at the drain side of the channel increases, eventually the junction will break down and give rise to a rapidly increasing avalanche current. The avalanched holes will accumulate in the potential pocket close to the interface, see FIGS. 9 a and b, which suddenly modify the potential near the surface (this being very significant and only possible in a low doped substrate). This corresponds to the very abrupt “pull-up” in the switching characteristics. When the carrier concentration reaches the level of the doping, the current becomes space-charge limited. This situation corresponds to the “high” plateau in the hysteresis characteristics. As for the descending direction and the “pull-down”, this was explained in [2] as a redistribution of the potential in the channel, when the free charge density again becomes less than the ionized acceptor density, which will cause the current to drop to the level of the subthreshold current. However, when comparing with characteristics observed in short channel devices [3] and SOI [4], this resembles a parasitic bipolar action, which is turned off, when the surface potential is reduced and the source-channel junction reverse biased.

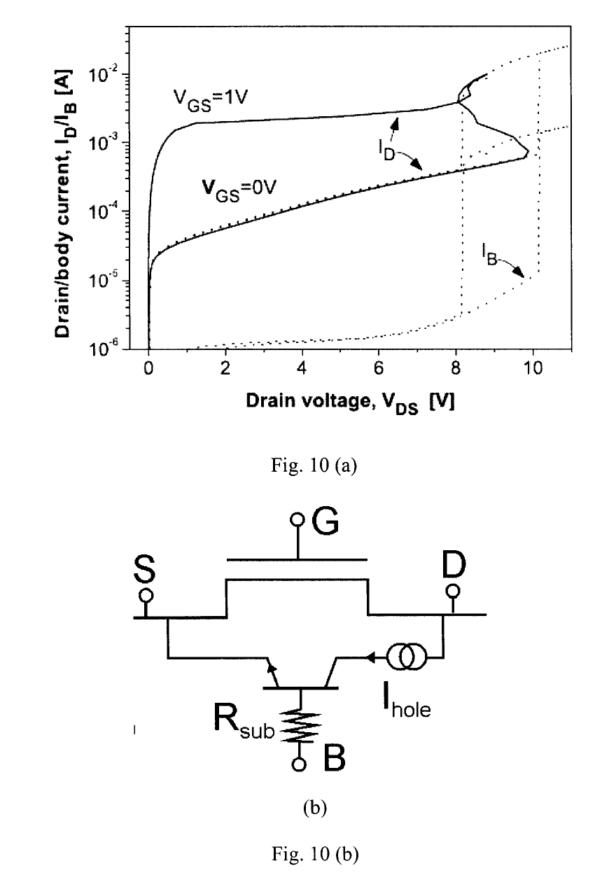

Experiments carried out using injected constant current in impact ionization revealed a drain current snap-back, see FIG. 10a illustrating a drain current snapback in V_{DS} (solid lines) measured using current biasing. Dotted lines show the corresponding hysteresis in I_{D} and I_{B}, measured using standard voltage biasing (V_{GS}=0V). Snapback demonstrates that the bipolar effect dictates the high-level transition of the hysteresis loop in PI-MOS.

This demonstrates that there is a bipolar effect that dictates the high-to-low-level transition of the hysteresis loop in PI-MOS and the equivalent device circuit is the one depicted in FIG. 10b (illustrating schematically a PI-MOS showing the bipolar action which is present in the avalanche region).

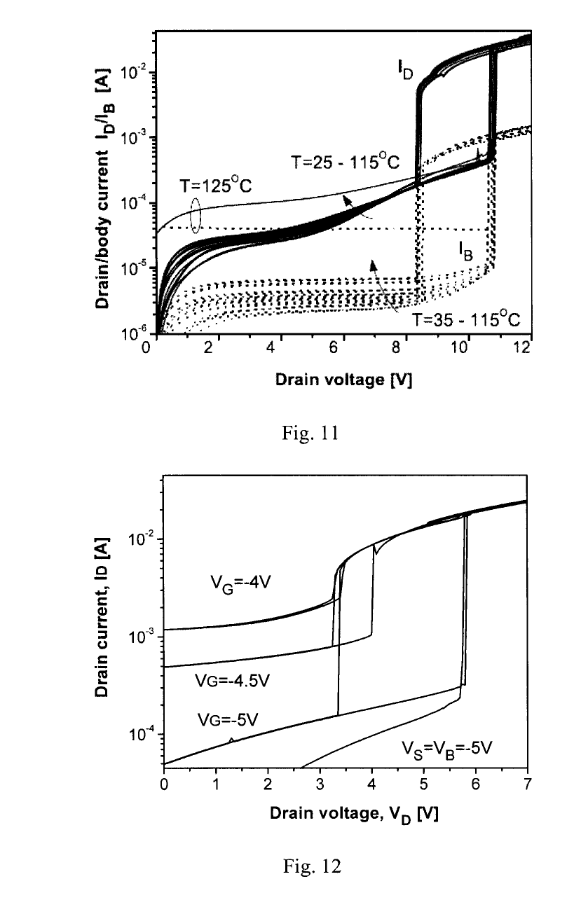

Moreover, this effect is responsible for the negative temperature coefficient and the high stability of the hysteresis loop up to around 115° C., see FIG. 11, which illustrates a effect of temperature (from 25° C. to 135° C. on I_{D} (solid lines) and I_{B} (dotted lines) hysteresis for a PI-MOS device with L=1.4 μm and Weff=40 μm.

Finally, it is essential to note that the condition of punch through requires the use of low doped substrates, and short channels. By proper tailoring of low doping levels and device length, it should also be possible to reduce biasing levels and make such an abrupt switch in nanometer scaled Ω-MOSFETs or multi-gate devices.

In the present discussion of all the operation regimes, we have used a source potential of 0V for simplicity, but as shown in FIG. 12, an alternative biasing scheme is also possible. By biasing the source with a negative potential, V_{S}, it is possible to reduce the absolute value of V_{D}, however the potential difference V_{DS} remains more or less constant. By a negative source bias, gate and substrate voltages must be adjusted accordingly.

In CMOS technologies, retrograde wells, where the doping level increases towards the bulk, are used to reduce the risk of latch-up, and similar profiles are used for threshold voltage control in scaled MOSFETs. The approach for the doping in an optimized PI-MOS is different: doping density is increased at the surface to reduce the MOSFET leakage, and the doping is reduced towards the substrate to increase the substrate resistance, thereby reducing the required substrate current to forward bias the source-substrate junction.

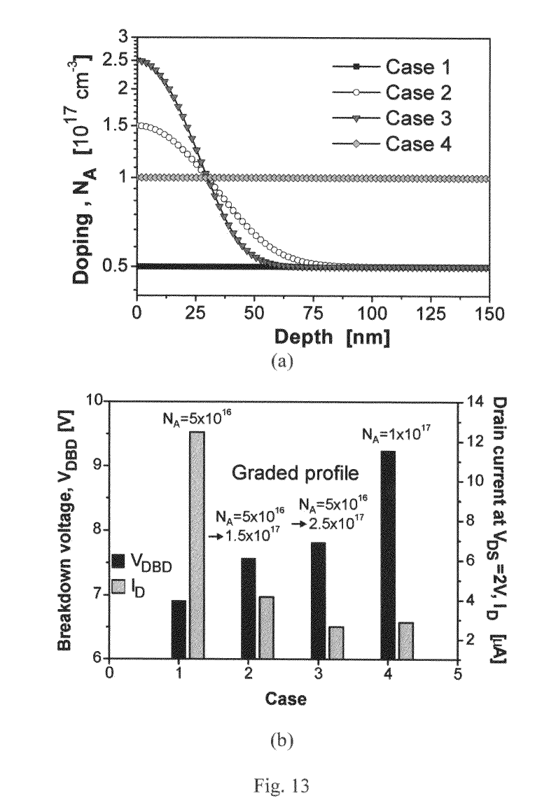

In FIG. 13 (a) four different doping profiles are shown. The breakdown voltages, as well as the subthreshold leakage at V_{DS}=2V, is displayed in FIG. 13 (b). A simple doubling of the channel doping from 5×10¹⁶ to 10¹⁷ cm⁻³ might reduce the leakage current by 77%, but will also increase the breakdown voltage by 34%. By using a graded profile going from 2.5×10¹⁷ cm⁻³ at the surface to 5×10¹⁶ cm⁻³ at a depth of around 30 nm (case 3), the same reduction in leakage current (79%) can be obtained, but with a much smaller increase in V_{DBD} of only 13%, the subthreshold slope remains unchanged. We conclude that a graded channel doping profile can improve the PIMOS properties compared to a constant channel doping [9]. The graded channel doping is easily obtained by an implantation/diffusion step.

### 4. Memory Architectures:

### 4.1 Memory Using the Drain Current-Drain Voltage Hysteresis:

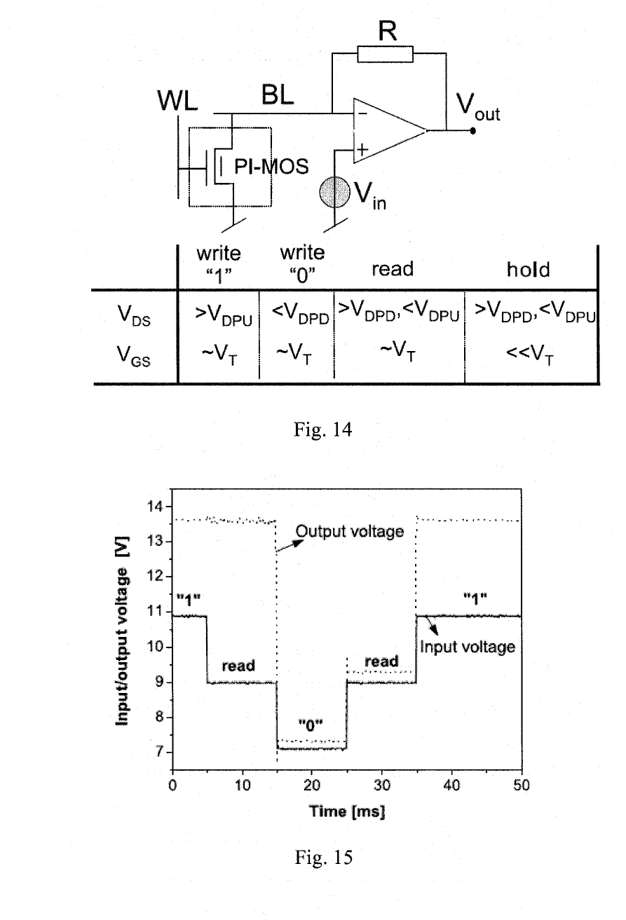

A novel 1T (one transistor) memory operation is proposed based on PI-MOS hysteresis in I_{D}(V_{DS}), see FIG. 14. Various memory alternatives are proposed as it follows.

1T-DRAM: FIG. 14 presents a first 1T DRAM memory cell architecture and its accompanying truth (operation) table. 1T DRAM structure using a single PI-MOS transistor with accompanying truth-table. An OpAmp is used to bias the drain of the IMOS memory transistor, so Vin=VDS. Applying a very negative VGS, i.e. −2V, during read can force the output down. However, the hold as well as the “0” level, do not go to zero, but only to an intermediate voltage level, since there is still non-negligible current flowing due to the high value of VDS. Off-chip discrete elements are used to implement electronics circuitry.

By proper layout this DRAM architecture can achieve 4F2 area [7]. A transimpedance amplifier is used to achieve the current to voltage conversion. A high-gain feedbacked OpAmp accomplish the V_{DS} biasing and manage the read write operation of this Memory cell. The memory characteristics are shown in FIG. 15 demonstrating the hold operation by pulling the V_{GS} low on the write “1”, read “1” cycle. As shown in this figure, the stored value is actually retrieved after hold, so there is potential for SRAM operation. However, whereas DRAM application is straightforward retrieval of the proper level without a reset is quite critical.

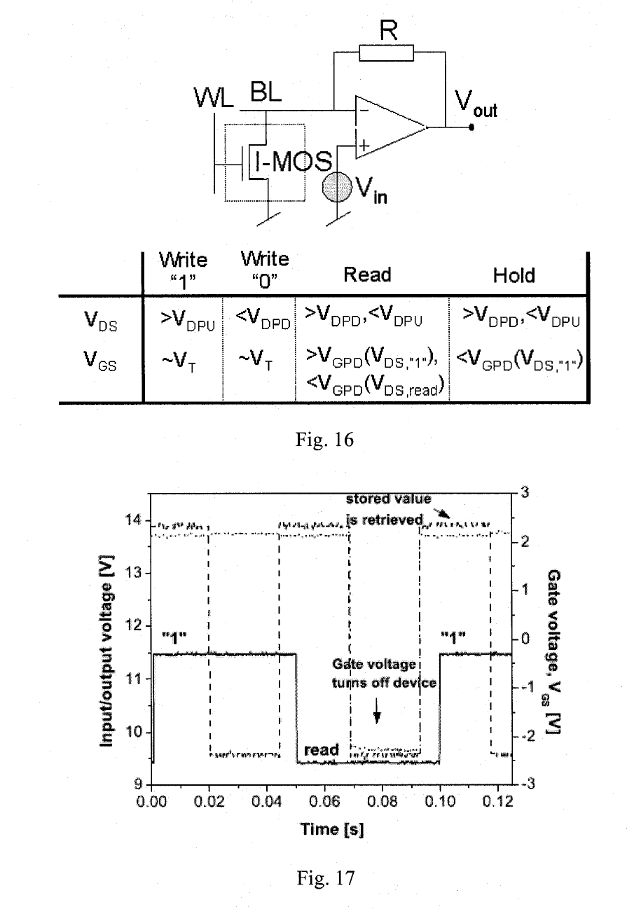

1T SRAM: A 1T SRAM memory based on PI-MOS is proposed by properly tuning both the ID-VDS and ID-VGS hysteresis loops, the architecture (identical to the 1T DRAM, and the truth table is shown in FIG. 16. The variation in V_{DS} is similar to the DRAM, but the “read” and “hold” value of V_{DS} and V_{GS} must be chosen carefully. For the read FIG. 17 shows the demonstration of the hold operation by pulling the V_{GS} low on the write ‘1’, read ‘1’ cycle.

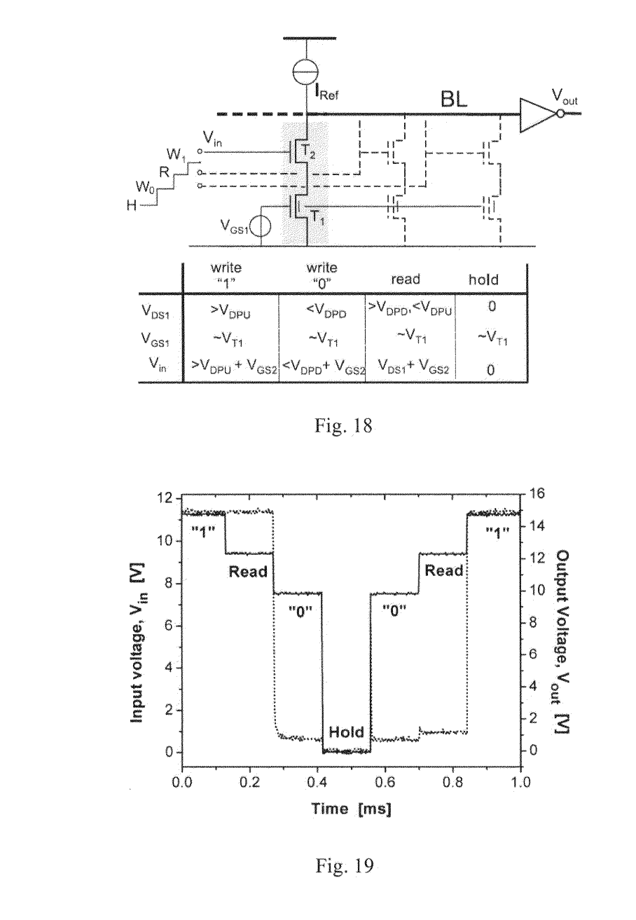

1T-1PI-MOS DRAM: A capacitor-less DRAM architecture (called 1T-1PI-MOS) but using an additional transistor T2 to write, read and address the PI-MOS memory cell is shown in FIG. 18, illustrating schematically a 1PI-MOS-1T DRAM architecture. The memory state is read through the ID of the storage transistors (T1) which corresponds to a PI-MOS device with hysteresis. A cascode stage follows the drain current of T1. The gate of the device T2 is driven by a multi-level voltage (Vin) that is used to set the voltage level of VDS1 in order to write, read and address the memory cell (T1). The output data is obtained by a current comparison at the bit line node (BL) with a reference current Iref whose value is adjusted in the middle of the range of current between state “1” and “0”. VT1 is the threshold voltage of the PI-MOS device in normal MOSFET operation, whereas VGS2 is the gate voltage of T2.

This has the advantage of completely shutting off current flow during hold, and thus reduces the power consumption, as seen in FIG. 19 which is an illustrative demonstration of the DRAM levels for both write “1” and read “1” the output reaches the full voltage swing, whereas for write “0”, read “0” and hold, it goes completely to zero or a negligible value of output voltage.

### 4.2 Memory Using the Drain Current-Gate Voltage Hysteresis:

The I_{D}(V_{GS}) hysteresis loops present in FIGS. 6 and 7 are proposed to define any other operation type of SRAM or DRAM memory cells based on PI-MOS. In this case abrupt switching and related hysteresis that define the memory window are achieved at high constant applied V_{DS}, when increasing and then decreasing the V_{GS} value, providing a general purpose, gate controlled, memory loop.

### 4.3 Abrupt Switch and Comparator Architectures:

The I_{D}(V_{DS}) and I_{D}(V_{GS}) characteristics of the PI-MOS device shows that this architecture is an excellent candidate as abrupt current switch by exploiting the pull-in and pull-out threshold voltages in the transfer characteristics of PI-MOS appearing under impact ionization and bipolar effects. The drain current transitions controlled by the gate voltage: current-low-to-current-high and current-high-to-current-low can offer a solution to go beyond the 60 mV/decade limit of a conventional MOSFET switch (transfer characteristics, drain current versus gate voltage).

PI-MOS is a new device with dynamic threshold voltages in both drain and gate voltages; i.e. a high threshold voltage when the control voltage is swept-up and a low threshold voltage when the current is swept-down (see FIGS. 5 and 7). The use of these threshold voltages to define a one-device (PI-MOS) based Schmitt trigger (or double-threshold comparator) operation is then proposed.

### 4.4 Optical Gate Memory Cell and Switch:

When the PIMOS is biased with the low current level in depletion (or beginning of weak inversion) it is proposed to trigger the pull-up event in FIGS. 4 and/or 6 by a pulse of light that will optically generate the initial conditions to multiply by impact ionization the carrier population. This will translate in an optical gate memory cell or in a very abrupt switching triggered by one or more photons, which can be used for single photon detection using PI-MOS. The low level can be then reached electrically, by reducing the applied voltages or by a combination of electrical and optical (dark) operation.

### 5. Retention Characteristics and Scaling:

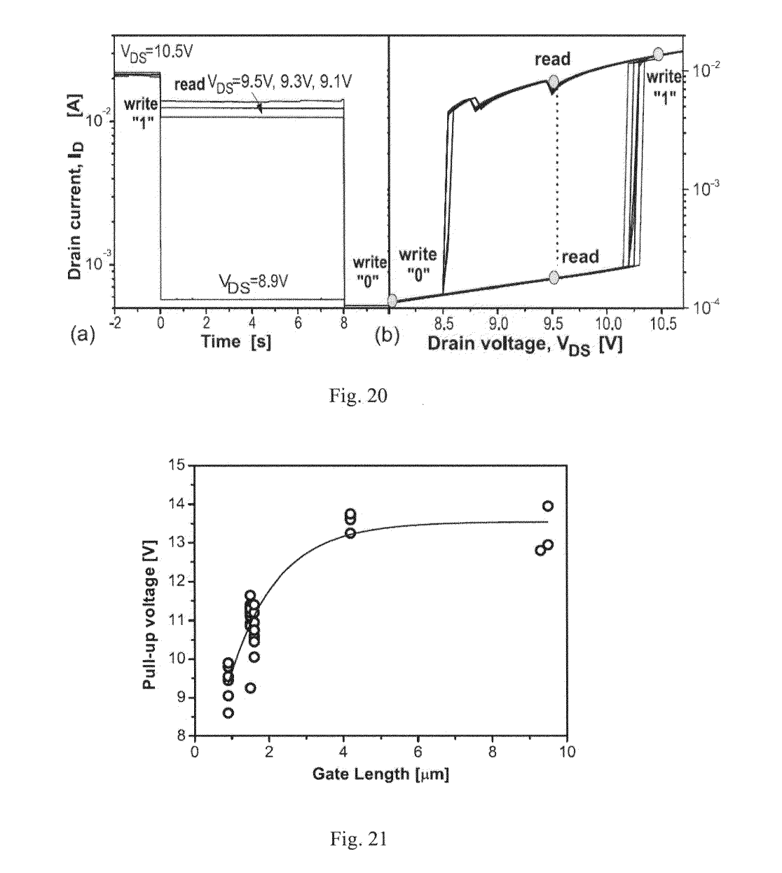

Retention time on the order of seconds is shown for convenience in FIG. 20 (a), illustrating retention time measurements for a device whose pull-up voltage is 9.7V, and pull-down 8.2V. The difference in current level between the “1” and read level, comes from the slope in the high state, and is not due to degradation but practically no retention degradation was observed.

FIG. 20 (b) shows 10 successive hysteresis cycles measured after operating the PIMOS for more than 10⁴ cycles, which suggest the PI-MOS memory cell a has very good reliability and robustness.

FIG. 21, a plot of breakdown/pull-up voltage as a function of channel length, shows that scaling the channel length, which reduces the needed drain voltage for impact ionization conditions, can scale the hysteresis window of the PI-MOS device down. Accordingly, the device size scales down and its speed scales up. In addition, the impact ionization is not the only factor responsible for the abrupt increase in ID: the accumulation of holes at the saddle point and the parasitic bipolar action contributes to the fast rise and the hysteresis characteristic. Thus, this breakdown may be obtainable with less energetic electrons, and thus a lower VDS and less hot carrier and better reliability compared to I-MOS devices proposed in [8].

### REFERENCES

1. J. R. Brews, “Geometrical Factors in Avalanche Punchthrough Erase”, IEEE Trans. Electron Dev., Vol. ED-24, No. 8, pp. 1108-1116, 1977.
2. A. Boudou and B. S. Doyle, “Hysteresis I-V effects in short-channel silicon MOSFET's,” Electron Device Letters, vol. 8 (7), pp. 300-302, 1987.
3. V. R. Rao, F. Wittmann, H. Gossner, and I. Eisele, “Hysteresis Behaviour in 85 nm Channel length Vertical n-MOSFET's Grwon by MBE”, IEEE Trans. Electron Dev. Vol. 43, No. 6, pp. 973-976, 1996.
4. G. A. Armstrong, J. R. Davis and A. Doyle, “Characterization of Bipolar Snapback and Breakdown Voltage in Thin-Film SOI Transistors by Two-Dimensional Simulation”, IEEE Trans. Electron Dev. Vol. 38, No. 2, pp. 328-336, 1991.
5. European Patent: 87401534.0, July 1987.
6. U.S. Pat. No. 4,843,442, June 1989.
7. S. Okhonin et al. Electron Dev. Letts., Vol. 23, pp. 85-87, 2002.
8. K. Gopalakrishnan, P. B. Griffin, and J. Plummer, “I-MOS: A novel semiconductor device with a subthreshold slope lower than kT/q,” IEDM Tech. Dig., 2002, pp. 289-292.
9. K. E. Moselund, D. Bouvet, V. Pott, C. Meinen, M. Kayal, A. M. Ionescu, “Punch-through impact ionization MOSFET (PIMOS): From device principle to applications,” Solid-State Electronics, In Press, Corrected Proof, Available online 21 May 2008: http://www.sciencedirect.com/science/journal/00381101.

1. A punch-through impact ionization Metal Oxide Semiconductor (PI-MOS) transistor fabricated on low doped or un-doped silicon, which presents hysteresis loops in output (drain current versus drain voltage) and transfer (drain current versus gate voltage) current-voltage characteristics when it is operated in a regime combining impact ionization and onset of a parasitic bipolar transistor.

2. A one punch-through impact ionization Metal Oxide Semiconductor (PI-MOS) transistor DRAM memory cell based on the abrupt hysteresis loop appearing in the output current-voltage characteristics (drain current versus drain voltage) of a PI-MOS transistor operated in its impact ionization regime.

3. A one punch-through impact ionization Metal Oxide Semiconductor (PI-MOS) transistor SRAM memory cell based on the combined use of the two hysteresis loops appearing in the output (drain current versus drain voltage) and transfer (drain current versus gate voltage) current-voltage characteristics of a PI-MOS transistor operated in its impact ionization regime.

4. A one MOS transistor or bipolar transistor—one punch-through impact ionization transistor (PI-MOS) DRAM memory cell with reduced power consumption, based on the abrupt hysteresis loop appearing in the output current-voltage characteristics (drain current versus drain voltage) of the PI-MOS transistor operated in its impact ionization regime.

5. A one punch-through impact ionization Metal Oxide Semiconductor (PI-MOS) transistor SRAM or DRAM memory cell using the abrupt hysteresis loop appearing in the transfer characteristics (drain current versus gate voltage) of a punch-through MOS transistor operated in impact ionization regime.

6. Use of a punch-through impact ionization Metal Oxide Semiconductor (PI-MOS) transistor as defined in claim 1 as an abrupt current switch by exploiting the pull-in and pull-out voltages in the output current-voltage characteristics of PI-MOS appearing under impact ionization and bipolar effects.

7. Use of a punch-through impact ionization Metal Oxide Semiconductor (PI-MOS) transistor as defined in claim 1 as abrupt current switch by exploiting the pull-in and pull-out threshold voltages in the transfer characteristics of PI-MOS appearing under impact ionization and bipolar effects.

8. Use of the abrupt current transitions defined in claim 5 to define a punch-through impact ionization Metal Oxide Semiconductor (PI-MOS) device with dynamic threshold voltages in both drain and gate voltages; a high threshold voltage when the control voltage is swept-up and a low threshold voltage when the current is swept-down.

9. Alternative punch-through impact ionization Metal Oxide Semiconductor (PI-MOS) architectures on bulk-silicon as gate-all-around, tri-gate, Fin-gate and planar transistor with same functionality as defined in claim 1.

10. Alternative punch-through impact ionization Metal Oxide Semiconductor (PI-MOS) architecture on silicon-on-insulator or silicon-on-nothing substrates as gate-all-around, double-gate, tri-gate, Fin-FET and single-gate transistor with same functionality as defined in claim 1.

11. Punch-through impact ionization Metal Oxide Semiconductor (PI-MOS) device with graded channel profile, using doping density increased at the surface to reduce the MOSFET leakage, and doping density reduced towards the substrate to increase the substrate resistance, thereby reducing the required substrate current to forward bias the source-substrate junction.

12. An abrupt optical gate switch and optically programmable memory cell based on a punch-through impact ionization Metal Oxide Semiconductor (PI-MOS), where the transition between the low and the high current level is triggered by one or more photons, when the device is biased with high drain voltage (near impact ionization) and low gate voltage (near depletion or weak inversion).
